(19) United States
(12) Patent Application Publication
(10) Pub. No.: US 2011/0176351 A1
(43) Pub. Date: Jul. 21, 2011

(54) NONVOLATILE MEMORY DEVICE AND METHOD FOR MANUFACTURING SAME

(75) Inventors: Ryota FUJITSUKA, Mie-ken (JP); Katsuyuki Sekine, Mie-ken (JP); Yoshio Ozawa, Kanagawa-ken (JP)

(73) Assignee: KABUSHIKI KAISHA TOSHIBA, Tokyo (JP)

(21) Appl. No.: 12/824,633

(22) Filed: Jun. 28, 2010

(30) Foreign Application Priority Data
Jan. 18, 2010 (JP) 2010-008131

(51) Int. Cl. G11C 11/00; H01L 21/8246

(52) U.S. Cl. 365/148; 438/384; 438/469; 257/E21.662

(57) ABSTRACT

According to one embodiment, a nonvolatile memory device includes a memory layer and a control unit. The memory layer includes a first conductive layer, a second conductive layer and a resistance change layer. The resistance change layer is provided between the first and second conductive layers and transits between a high resistance state and a low resistance state by at least one of an applied electric field and an applied current. The control unit is electrically connected to the first and second conductive layers and configured to apply a first signal with a first polarity between the first and second conductive layers prior to applying a second signal with a second polarity different from the first polarity between the first and second conductive layers to cause the resistance change layer to transit from the high resistance state to the low resistance state.

### CROSS-REFERENCE TO RELATED APPLICATIONS

This application is based upon and claims the benefit of priority from the prior Japanese Patent Application No. 2010-008131, filed on Jan. 18, 2010; the entire contents of which are incorporated herein by reference.

### FIELD

Embodiments described herein relate generally to a nonvolatile memory device and a method for manufacturing the same.

### BACKGROUND

A resistance change memory has received attention as a nonvolatile memory in the next generation, as its characteristics are hard to deteriorate even in downscaling and it is easy to achieve high capacity. In the resistance change memory, characteristics in which a resistance of a resistance change layer varies with a voltage applied to the resistance change layer and a current applied therethrough are utilized.

With respect to the resistance change layer, a forming treatment to form a conductive filament having the changeable resistance is performed after formation of an element. At this time, simultaneously with the formation of the conductive filament, charges are trapped inside the resistance change layer, and when the charges are discharged during the data retention, an energy potential in the resistance change layer changes. This leads to a change of the resistance of the resistance change layer and deterioration of the data retention characteristics.

Similarly, charges may be trapped inside the resistance change layer also during a writing operation to cause the resistance change layer to be in a low resistance state, for example, and during an erasing operation to cause the resistance change layer to be in a high resistance state, for example. In these cases as well, the charges deteriorate the data retention characteristics.

### BRIEF DESCRIPTION OF THE DRAWINGS

FIG. 1 is a flow chart illustrating the operation of a nonvolatile memory device according to a first embodiment;

FIGS. 2A and 2B are schematic views illustrating the operation of the nonvolatile memory device according to the first embodiment;

FIGS. 3A to 3C are schematic views illustrating the configuration of the nonvolatile memory device according to the first embodiment;

FIG. 4 is a schematic cross-sectional view illustrating the configuration of the nonvolatile memory device according to the first embodiment;

FIG. 5 is a schematic view illustrating the configuration of the nonvolatile memory device according to the first embodiment;

FIGS. 6A to 6C are schematic cross-sectional views illustrating the operation of the nonvolatile memory device according to the first embodiment;

FIGS. 7A to 7C are schematic cross-sectional views illustrating the operation of a nonvolatile memory device according to a comparative example;

FIGS. 8A and 8B are schematic views illustrating the operation of the nonvolatile memory device according to the first embodiment;

FIG. 9 is a flow chart illustrating the operation of a nonvolatile memory device according to a second embodiment;

FIGS. 10A and 10B are schematic views illustrating the operation of the nonvolatile memory device according to the second embodiment;

FIGS. 11A and 11B are schematic views illustrating the operation of the nonvolatile memory device according to the second embodiment;

FIG. 12 is a flow chart illustrating a method for manufacturing a nonvolatile memory device according to a third embodiment;

FIGS. 13A and 13B are schematic views illustrating the method for manufacturing a nonvolatile memory device according to the third embodiment; and

FIGS. 14A and 14B are schematic views illustrating the method for manufacturing a nonvolatile memory device according to the third embodiment.

### DETAILED DESCRIPTION

In general, according to one embodiment, a nonvolatile memory device includes a memory layer and a control unit. The memory layer includes a first conductive layer, a second conductive layer and a resistance change layer. The resistance change layer is provided between the first conductive layer and the second conductive layer. The resistance change layer is configured to transit between a high resistance state and a low resistance state having a resistance lower than a resistance in the high resistance state by at least one of an applied electric field and an applied current. The control unit is electrically connected to the first conductive layer and the second conductive layer. The control unit is configured to apply a first signal with a first polarity between the first conductive layer and the second conductive layer prior to applying a second signal with a second polarity different from the first polarity between the first conductive layer and the second conductive layer to cause the resistance change layer to transit from the high resistance state to the low resistance state.

According to another embodiment, a nonvolatile memory device includes a memory layer and a control unit. The memory layer includes a first conductive layer, a second conductive layer and a resistance change layer. The resistance change layer is provided between the first conductive layer and the second conductive layer. The resistance change layer is configured to transit between a high resistance state and a low resistance state having a resistance lower than a resistance in the high resistance state by at least one of an applied electric field and an applied current. The control unit is electrically connected to the first conductive layer and the second conductive layer. The control unit is configured to apply a third signal with a first polarity between the first conductive layer and the second conductive layer prior to applying a fourth signal with a second polarity different from the first polarity between the first conductive layer and the second conductive layer to cause the resistance change layer to transit from the low resistance state to the high resistance state.

According to another embodiment, a method for manufacturing a nonvolatile memory device is disclosed. The device includes a memory layer and a control unit. The memory layer includes a first conductive layer, a second conductive layer and a resistance change layer. The resistance change layer is provided between the first conductive layer and the second conductive layer. The resistance change layer is configured to transit between a high resistance state and a low resistance state having a resistance lower than a resistance in the high resistance state by at least one of an applied electric field and an applied current. The control unit is electrically connected to the first conductive layer and the second conductive layer. The control unit is configured to apply a set pulse with a first polarity between the first conductive layer and the second conductive layer to cause the resistance change layer to transit from the high resistance state to the low resistance state, and to apply a reset pulse with the first polarity between the first conductive layer and the second conductive layer to cause the resistance change layer to transit from the low resistance state to the high resistance state. The method includes forming the first conductive layer, forming a resistance change film serving as the resistance change layer above the first conductive layer, forming the second conductive layer above the resistance change film, and applying a forming voltage between the first conductive layer and the second conductive layer to form a current path in the resistance change film prior to applying a reverse polarity voltage. The reverse polarity voltage has a polarity different from a polarity of the forming voltage.

Hereinafter, embodiments of the invention will be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among drawings, even for identical portions.

In the specification of the application and the drawings, components similar to those described previously in regard to the earlier drawings are marked with like reference numerals, and a detailed description is omitted as appropriate.

### First Embodiment

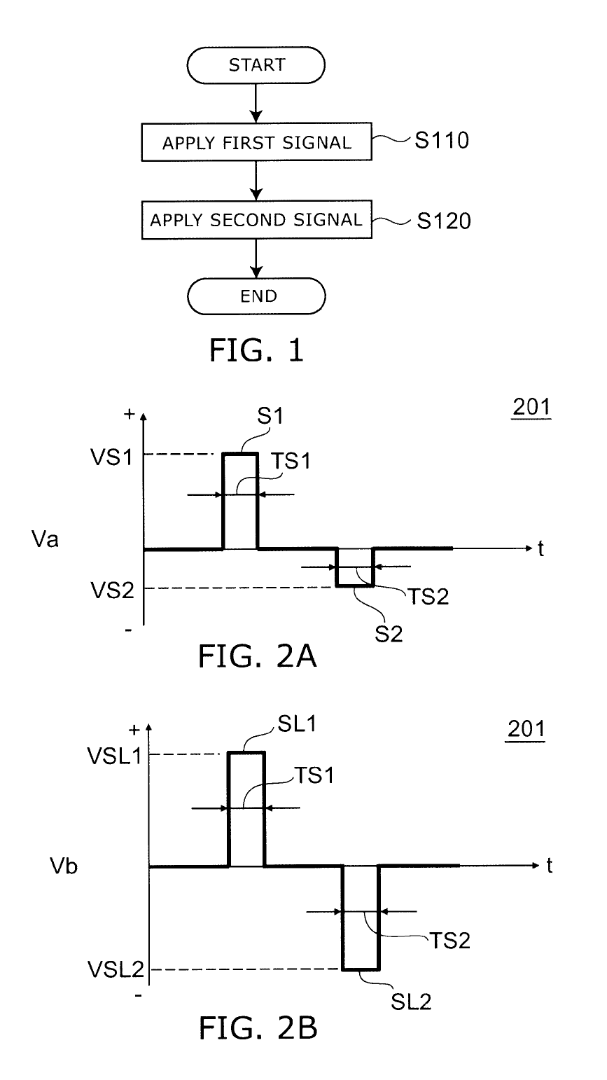

FIG. 1 is a flow chart illustrating the operation of a nonvolatile memory device according to a first embodiment of the invention.

FIGS. 2A and 2B are schematic views illustrating the operation of the nonvolatile memory device according to the first embodiment of the invention.

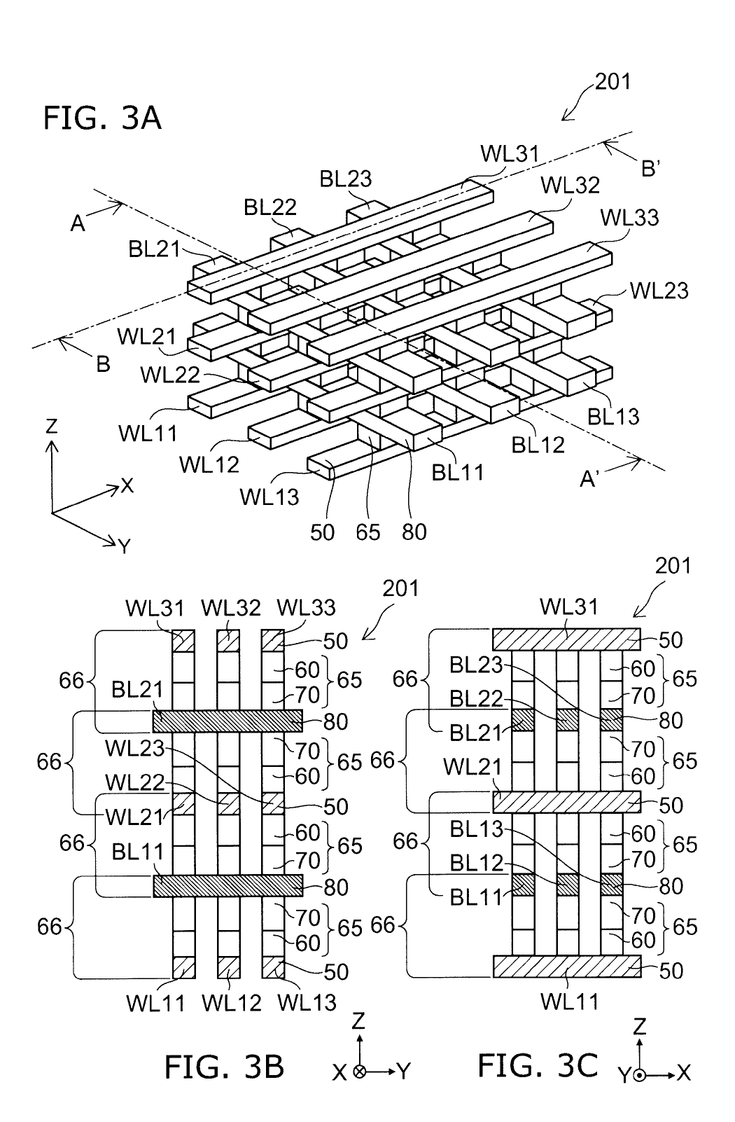

FIGS. 3A to 3C are schematic views illustrating the configuration of the nonvolatile memory device according to the first embodiment of the invention.

More specifically, FIG. 3A is a schematic perspective view, FIG. 3B is a cross-sectional view along A-A′ line in FIG. 3A, and FIG. 3C is a cross-sectional view along B-B′ line in FIG. 3A.

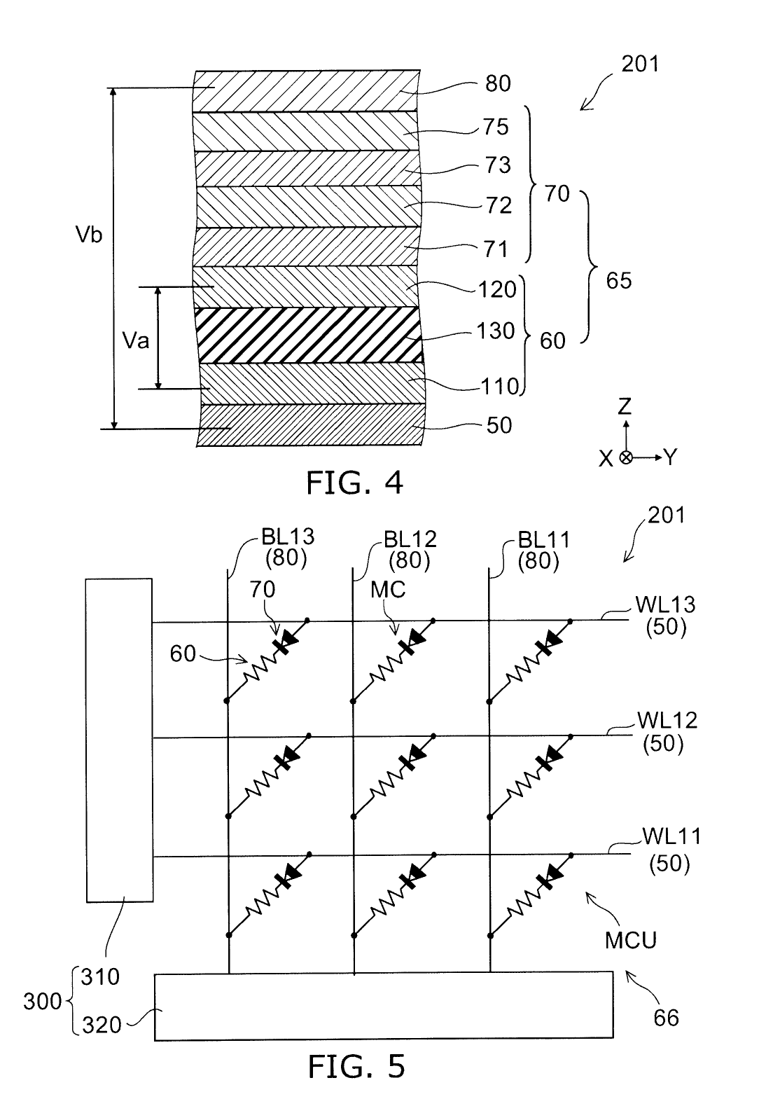

FIG. 4 is a schematic cross-sectional view illustrating the configuration of the nonvolatile memory device according to the first embodiment of the invention.

More specifically, FIG. 4 is a cross-sectional view corresponding to part of the cross-section along the A-A′ line in FIG. 3A, and illustrates one portion of memory cells MC illustrated in FIG. 3A.

FIG. 5 is a schematic view illustrating the configuration of the nonvolatile memory device according to the first embodiment of the invention.

The nonvolatile memory device according to this embodiment is an example of a cross-point type nonvolatile memory device. Hereinafter, the outline of the entire configuration of this nonvolatile memory device will be described with FIGS. 3A to 3C, FIG. 4 and FIG. 5.

As shown in FIGS. 3A to 3C, a nonvolatile memory device 201 includes, for example, a plurality of stacked component memory layers 66.

Each of the component memory layers 66 includes first interconnections 50, second interconnections 80 provided nonparallel to the first interconnections 50, and stacked structure units 65 provided between one of the first interconnections 50 and one of the second interconnections 80. Each of the stacked structure units includes a memory layer 60 and a rectifying element 70.

Here, a stacking direction of the memory layer 60 and the rectifying element 70 is taken as a Z-axis direction. One direction perpendicular to the Z-axis is taken as an X-axis direction and a direction perpendicular to the Z-axis and the X-axis is taken as a Y-axis direction.

For example, in the lowermost component memory layer of the nonvolatile memory device 201, the first interconnections 50 are word lines WL11, WL12 and WL13, the second interconnections 80 are bit lines BL11, BL12 and BL13. For example, in the lowermost component memory layer 66, the first interconnections 50 align in the X-axis direction and the second interconnections 80 align in the Y-axis direction orthogonal to the X-axis direction. The first interconnections 50, the second interconnections 80 and the stacked structure units 65 provided between them are stacked in the Z-axis direction orthogonal to the X-axis direction and the Y-axis direction.

Moreover, in the second component memory layer 66 from the bottom, the first interconnections 50 are word lines WL21, WL22 and WL23 and the second interconnections 80 are the bit lines BL11, BL12 and BL13.

Furthermore, in the third component memory layer 66 from the bottom, the first interconnections 50 are word lines WL21, WL22 and WL23 and the second interconnections 80 are bit lines BL21, BL22 and BL23.

Furthermore, in the topmost component memory layer 66 (the fourth one from the bottom), the first interconnections 50 are word lines WL31, WL32 and WL33 and the second interconnections 80 are the bit lines BL21, BL22 and BL23. The respective word lines are collectively referred to as “word lines WL”, and the respective bit lines are collectively referred to as “bit lines BL”.

In the nonvolatile memory device 201, four layers of the component memory layers 66 are stacked, but in the nonvolatile memory device 201 according to this embodiment, the number of the stacked component memory layers 66 is arbitrary. The nonvolatile memory device 201 like this can be provided on a semiconductor substrate, and in that case, each layer of the component memory layers 66 can be disposed in parallel to a major surface of the semiconductor substrate. That is, the component memory layers 66 are multiply stacked in parallel to the major surface of the substrate.

It is noted that inter-layer insulating films not shown are provided between each of the above first interconnections 50, each of the second interconnections 80 and each of the stacked structure units 65, and between one another.

In FIGS. 3A to 3C, three first interconnections 50 and three second interconnections 80 in the respective component memory layers 66 are illustrated to avoid complication, however the numbers of the first interconnections 50 and the second interconnections 80 are arbitrary in the nonvolatile memory device 201 according to this embodiment. The number of the first interconnections 50 may be different from the number of the second interconnections 80.

In this specific example, the first interconnections 50 and the second interconnections 80 are used for the each of the component memory layers 66 adjacent to each other. Namely, as illustrated in FIGS. 3A to 3C, the word lines WL21, WI22 and WL23 are used in both upper and lower component memory layers 66, and the bit lines BL11, BL12 and BL13 and the bit lines BL21, BL22 and BL23 are used in both upper and lower component memory layers 66.

However, the embodiment is not limited to the above, the word lines WL and the bit lines BL may be provided independently in each of the component memory layers 66. In the case where the word lines WL and the bit lines BL are provided independently in each of the component memory layers 66, the aligning direction of the word lines WL and the aligning direction of the bit lines BL may be changed in each of the component memory layers 66.

Moreover, here, the first interconnections 50 are taken as the word lines WL and the second interconnections 80 are taken as the bit lines BL, however the first interconnections 50 may be taken as the bit lines BL and the second interconnections 80 may be taken as the word lines WL. That is, the bit lines BL and the word lines WL are exchangeable each other. In the following, the description will be made assuming that the first interconnections 50 are the word lines WL and the second interconnections 80 are the bit lines BL.

As shown in FIGS. 3B and 3C, the stacked structure unit 65 including the memory layer 60 and the rectifying element 70 is provided at a portion (cross-point) where the first interconnection 50 and the second interconnection 80 cross three-dimensionally in each of the component memory layers 66. The memory layer 60 placed at each cross-point serves as one memory unit. The stacked structure unit 65 including this memory layer 60 is taken as one memory cell MC.

In examples shown in FIGS. 3B and 3C, the memory layer 60 is provided on a side of the first interconnection 50 and the rectifying element 70 is provided on a side of the second interconnection 80, however the rectifying element 70 may be provided on the side of the first interconnection 50 and the memory layer 60 may be provided on the side of the second interconnection 80. Furthermore, the stacking order of the memory layer 60 and the rectifying element 70 may be changed for each component memory layer 66.

As shown in FIG. 4, the memory layer 60 includes a first conductive layer 110, a second conductive layer 120, a resistance change layer 130 provided between the first conductive layer 110 and the second conductive layer 120. The resistance change layer 130 transits between a high resistance state and a low resistance state having a resistance lower than a resistance in the high resistance state by at least one of an electric field applied to the resistance change layer 130 and a current applied through the resistance change layer 130.

The resistance change layer 130 is illustratively based on transition metal oxides. More specifically, the resistance change layer 130 can be illustratively based on the transition metal oxides such as HfO₂, ZrO₂, NiO, TiO and Ta₂O₅ or the like. The resistance change layer 130 can be based on these transition metal oxides doped with an additive. Furthermore, the resistance change layer 130 can be based on stacked films of a silicon oxide film and a transition metal oxide film such as HfO₂ or the like. The resistance change layer 130 can be based on a film such that a transition metal element such as Hf or the like is added into a silicon oxide film.

As shown in FIG. 4, the rectifying element 70 may include an n-type semiconductor layer 71 (for example, n-type Si layer), a rectifying element electrode 75, an intrinsic semiconductor layer 72 (for example, i-Si layer) provided between the n-type semiconductor layer 71 and the rectifying element electrode 75, and a p-type semiconductor layer 73 (for example, p-type Si layer) provided between the intrinsic semiconductor layer 72 and the rectifying element electrode 75.

That is, the rectifying element 70 can be based on a pin diode having stacked films in which a p-type impurity and an n-type impurity are doped into a poly-crystalline silicon layer, for example. However, this embodiment is not limited thereto, but the rectifying element 70 can be based on various diodes such as a Schottky diode having a Schottky barrier formed at an interface between a metal and a semiconductor, and a MIM (Metal Insulator Metal) diode having a stacked structure of metal/insulator/metal or the like.

In this specific example, the second conductive layer 120 is disposed on a rectifying element 70 side in the memory layer 60, but the first conductive layer 110 may be disposed on the rectifying element 70 side. The second conductive layer 120 may be regarded as part of the rectifying element 70. Moreover, in FIG. 4, another electrode may be provided between the second conductive layer 120 and the n-type semiconductor layer 71. The rectifying element electrode 75 may be used as the second interconnection 80 and the rectifying element electrode 75 may be omitted.

The relationship between a forward direction in which a current is easy to flow in the rectifying element 70 and a stacking direction of the rectifying element 70 and the memory layer 60 (resistance change layer 130) is arbitrary. That is, the memory layer 60 (resistance change layer 130) may be disposed on a forward direction side of the rectifying element 70 and the memory layer 60 (resistance change layer 130) may be disposed on an opposite side to the forward direction of the rectifying element 70.

Depending on the disposition of the memory layer 60 and the rectifying element 70, the first conductive layer 110 may be used as the first interconnection 50 or the second interconnection 80. The second conductive layer 120 may be used as the first interconnection 50 or the second interconnection 80.

Thus, the configuration of the stacked structure unit 65 may have various variations.

In this specific example, the first conductive layer 110 is illustratively based on a material which forms an ohmic contact with the first interconnection 50. The second conductive layer 120 is illustratively based on a material which forms an ohmic contact with the rectifying element 70. The rectifying element electrode 75 is illustratively based on a material which forms an ohmic contact with the second interconnection 80.

As shown in FIG. 4, a voltage between the first conductive layer 110 and the second conductive layer 120 is taken as a resistance change layer voltage Va. A voltage between the first interconnection 50 and the second interconnection 80 is taken as a stacked structure unit voltage Vb.

FIG. 5 illustrates the configuration of one component memory layer 66 illustrated in FIGS. 3A to 3C.

As shown in FIG. 5, the nonvolatile memory device 201 includes a memory cell unit MCU and a control unit 300. The memory cell unit MCU has the configuration described with regard to FIGS. 3A to 3C and FIG. 4. In each of the component memory layers 66 of the memory cell unit MCU, the memory cells MC are disposed in a matrix configuration.

The control unit 300 includes a word line circuit 310 illustratively connected to the word lines WL11, WL12 and WL13, and a bit line circuit 320 illustratively connected to the bit lines BL11, BL12 and BL13. The word line circuit 310 includes, for example, a row decoder and the bit line circuit 320 includes, for example, a sense amplifier circuit. The word lines WL are selected by the word line circuit 310. The bit line circuit 320 detects the data in reading operation, holds the writing data in data writing operation and controls the voltage of the bit lines BL correspondingly.

Various electric signals applied from the control unit 300 are applied to the stacked structure units 65 (memory layer 60 and rectifying element 70) provided at the cross-points where the word lines WL11, WL12 and WL13 and the bit lines BL11, BL12 and BL13 cross three-dimensionally. Namely, the control unit 300 is electrically connected to the first conductive layer 110 and the second conductive layer 120 of the stacked structure unit 65.

The resistance state of the resistance change layer 130 of the memory layer 60 is controlled to be one of the high resistance state and the low resistance state by the electric signal provided from the control unit 300, and the different resistance states are used as data storing information.

FIG. 5 illustrates the configuration of one component memory layer 66 illustrated in FIGS. 3A to 3C and another component memory layer 66 has the similar configuration as well. That is, the control unit 300 is connected to the word lines and the bit lines included in each component memory layer 66. That is, the control unit 300 is electrically connected to the first interconnections 50 and the second interconnections 80 in each component memory layer 66.

An operation to cause the resistance change layer 130 to transit from the high resistance state to the low resistance state is referred to be a set operation. An operation to cause the resistance change layer 130 to transit from the low resistance state to the high resistance state is referred to be a reset operation.

It is noted that, in the following, for convenience of description, the case where the resistance state of the resistance change layer 130 has two states of the high resistance state and the low resistance state is described, however the resistance change layer 130 may have three or more or four or more resistance states. Namely the nonvolatile memory device 201 may be a multiple-valued memory.

Thus, the nonvolatile memory device 201 according to this embodiment includes the memory layer 60 including the first conductive layer 110, the second conductive layer 120, and the resistance change layer 130 provided between the first conductive layer 110 and the second conductive layer 120 and transits between the high resistance state and the low resistance state having a resistance lower than a resistance in the high resistance state by at least one of the applied electric field and the applied current; and the control unit 300 electrically connected to the first conductive layer 110 and the second conductive layer 120.

As shown in FIG. 1, in the nonvolatile memory device 201, the control unit 300 applies a first signal with a first polarity between the first conductive layer 110 and the second conductive layer 120 (step S110) prior to applying a second signal with a second polarity different from the first polarity between the first conductive layer 110 and the second conductive layer 120 (step S120) in the set operation (the operation to cause the resistance change layer 130 to transit from the high resistance state to the low resistance state).

FIGS. 2A and 2B illustrate the resistance change layer voltage Va being a voltage between the first conductive layer 110 and the second conductive layer 120 and the stacked structure unit voltage Vb being a voltage between the first interconnection 50 and the second interconnection 80, respectively. In these figures, the horizontal axis indicates time t, the vertical axis in FIG. 2A indicates the resistance change layer voltage Va and the vertical axis in FIG. 2B indicates the stacked structure unit voltage Vb.

As shown in FIG. 2A, in the set operation, a first signal S1 with the first polarity is applied between the first conductive layer 110 and the second conductive layer 120 (step S110). In this specific example, the first polarity is a positive polarity. After applying the first signal S1, a second signal S2 with the second polarity different from the first polarity is applied between the first conductive layer 110 and the second conductive layer 120 (step S120). In this specific example, the second polarity is a negative polarity.

The first polarity may be the negative polarity and the second polarity may be the positive polarity.

Thus, the resistance change layer voltage Va includes the first signal S1 and the second signal S2 applied after the first signal S1 is applied.

For example, the first signal S1 is a signal for the set operation. The second signal S2 with the polarity reverse to the first signal S1 is a signal for de-trapping charges trapped in the resistance change layer 130.

A voltage of the first signal S1 is taken as a first signal voltage VS1, and an applied time of the first signal S1 is taken as a first signal time TS1. A voltage of the second signal S2 is taken as a second signal voltage VS2, and an applied time of the second signal S2 is taken as a second signal time TS2. A magnitude of the first signal voltage VS1 corresponds to a magnitude of the electric field in the resistance change layer 130 when the first signal S1 is applied. A magnitude of the second signal voltage VS2 corresponds to a magnitude of the electric field in the resistance change layer 130 when the second signal S2 is applied.

At least one of that the absolute value of the second signal voltage VS2 is smaller than the absolute value of the first signal voltage VS1 and that the second signal time TS2 is shorter than the first signal time TS1 may be enforced.

That is, the magnitude of the electric field in the resistance change layer 130 when the second signal S2 is applied is smaller than the magnitude of the electric field in the resistance change layer 130 when the first signal S1 is applied. The time (second signal time TS2) during the application of the electric field by the second signal S2 to the resistance change layer 130 is shorter than the time (first signal time TS1) during the application of the electric field by the first signal S1 to the resistance change layer 130.

Here, it is preferable that the absolute value of the effective electric field applied to the resistance change layer 130 by the above second signal S2 is larger than 0 MV/cm (mega-volt/centimeter) and not more than approximately 10 MV/cm. Thereby, de-trapping can be performed with substantially no change in the characteristics of the resistance change layer 130.

The second signal time TS2 being an applied time of the above second signal S2 can be set to be not less than 100 ps (picosecond) and not more than 1 ms (millisecond).

Thus, after the first signal S1 for the set operation is applied to the resistance change layer 130, the second signal S2 with the polarity reverse to the first signal S1 having a small absolute value of the voltage and/or a short applied time is applied to the resistance change layer 130. Thereby the charges trapped in the resistance change layer 130 are preliminary de-trapped with substantially no bad effect to the resistance state (low resistance state under the set state) of the resistance change layer 130. Thus, the change of the internal electric field in the resistance change layer 130 during the later data retention can be suppressed and a nonvolatile memory device with excellent data retention characteristics can be provided.

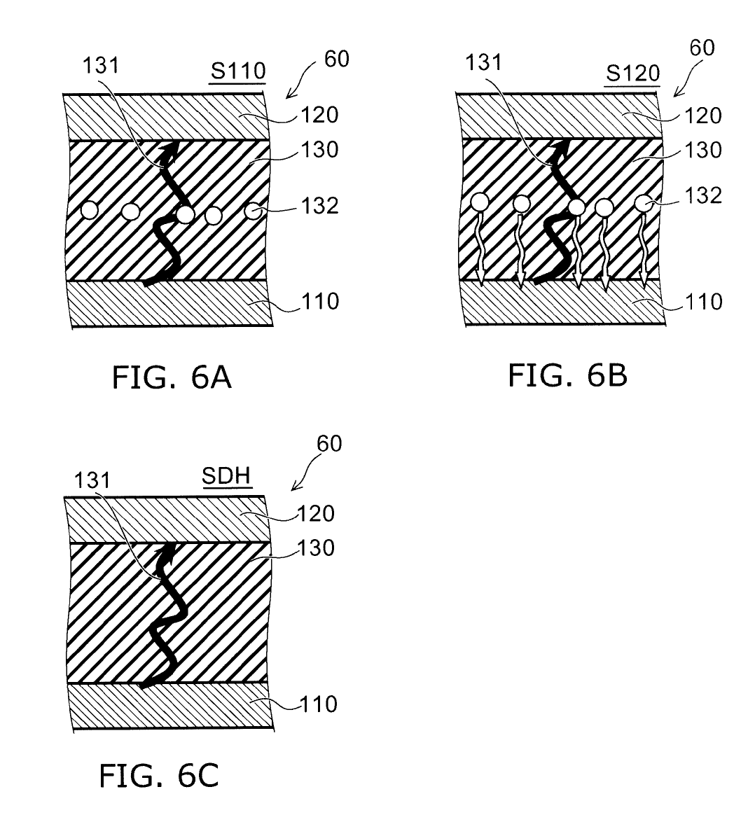

FIGS. 6A to 6C are schematic cross-sectional views illustrating the operation of the nonvolatile memory device according to the first embodiment of the invention.

That is, these figures illustrate schematically the states of the memory layer 60 of the nonvolatile memory device 201. FIG. 6A corresponds to the state after the step S110, FIG. 6B corresponds to the state after the step S120 and FIG. 6C corresponds to the state after long time elapses from the step S120, namely the state during a data retention period SDH.

As shown in FIG. 6A, the first signal 51 for the set operation is applied to the resistance change layer 130. In the resistance change layer 130, a filament 131 serving as a conducting path is formed and the resistance of the resistance change layer 130 turns into the low resistance state. At this time, charges 132 are trapped simultaneously in the resistance change layer 130.

As shown in FIG. 6B, thereafter, by applying the second signal S2 with the polarity reverse to the first signal S1 to the resistance change layer 130, the charges 132 trapped in the resistance change layer 130 are de-trapped.

Thereby, as shown in FIG. 6C, during the data retention period SDH, the change of the internal electric field in the resistance change layer 130 due to migration of the charges 132 does not occur because the charge 132 is not substantially trapped in the resistance change layer 130. Therefore, the change of the resistance value of the resistance change layer 130 is suppressed and the data retention characteristics are excellent.

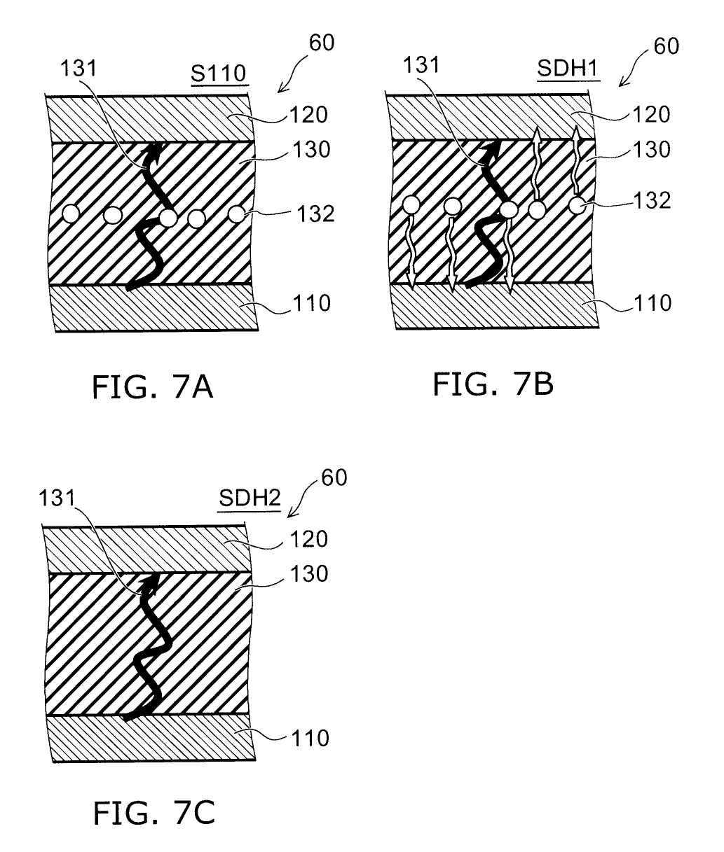

FIGS. 7A to 7C are schematic cross-sectional views illustrating the operation of a nonvolatile memory device according to a comparative example.

In the nonvolatile memory device of the comparative example, in the set operation, only step S110 to apply the first signal S1 is performed and the step S120 to apply the second signal S2 is not performed. FIG. 7A corresponds to the state after the step S110, FIG. 7B corresponds to the state of a first data retention period SDH1 after time elapses from the step S110 and FIG. 7C corresponds to the state of a second data retention period SDH2 after additional time elapses from the above first data retention period SDH1.

As shown in FIG. 7A, when the first signal S1 for the set operation is applied to the resistance change layer 130, the resistance of the resistance change layer 130 turns into the low resistance state and the charges 132 are simultaneously trapped into the resistance change layer 130.

As shown in FIG. 7B, thereafter, the charges trapped in the resistance change layer 130 are gradually de-trapped during the first data retention period SDH1.

As shown in FIG. 7C, in the second data retention period SDH2 after the additional time elapses, the charges 132 trapped in the resistance change layer 130 are de-trapped and disappear from the resistance change layer 130.

Thus, the state of the charges 132 trapped in the resistance change layer 130 (for example, the amount of charges 132) changes between the first data retention period SDH1 which is the initial stage during the data retention period and the second data retention period SDH2 after the time elapses. Thereby, the internal electric field in the resistance change layer 130 changes, and as a result, the resistance of the resistance change layer 130 changes. Thus, the data retention characteristics are bad in the nonvolatile memory device of the comparative example.

In contrast, in the nonvolatile memory device 201 according to this embodiment, the charges trapped in the resistance change layer 130 are preliminarily de-trapped before the data retention period SDH by applying the first signal S1 and the second signal S2 with the polarity reverse to the first signal S1 in combination. Thereby the change of the internal electric field in the resistance change layer 130 during the later data retention period SDH can be suppressed and the data retention characteristics can be improved.

In this way, as shown in FIG. 2A, the control unit 300 applies the resistance change layer voltage Va having a waveform which combines the first signal S1 with the second signal S2 with the polarity reverse to the first signal S1 to the resistance change layer 130 (between the first conductive layer 110 and the second conductive layer 120).

To perform the operation like this, the control unit 300 applies the stacked structure unit voltage Vb having a waveform illustrated in FIG. 2B to the stacked structure unit 65.

That is, in the set operation, the control unit 300 applies a first interconnection signal SL1 with the first polarity (positive polarity in this specific example) between the first interconnection 50 and the second inter connection 80. After applying the first interconnection signal SL1, the control unit 300 applies a second interconnection signal SL2 with the second polarity (negative polarity in this specific example) different from the first polarity between the first interconnection 50 and the second interconnection 80.

The voltage of the first interconnection signal SL1 is taken as a first interconnection signal voltage VSL1. An applied time of the first interconnection signal SL1 is substantially the same as the first signal time TS1. The voltage of the second interconnection signal SL2 is taken as a second interconnection signal voltage VSL2. An applied time of the second interconnection signal SL2 is substantially the same as the second signal time TS2.

Because the first interconnection signal voltage VSL1 is divided to be applied to each of the memory layer 60 (resistance change layer 130) and the rectifying element 70, the first interconnection signal voltage VSL1 is not necessary to be identical to the first signal voltage VS1.

Because the second interconnection signal voltage VSL2 is divided to be applied to each of the memory layer 60 (resistance change layer 130) and the rectifying element 70, the second interconnection signal voltage VSL2 is not necessary to be identical to the second signal voltage VS2.

As previously described, the absolute value of the second signal voltage VS2 is set smaller than the absolute value of the first signal voltage VS1 in order to make the electric field in the resistance change layer 130 during applying the second signal S2 smaller than during applying the first signal S1. However, at this time, the absolute value of the second interconnection signal voltage VSL2 is not necessary to be set smaller than the absolute value of the first interconnection signal voltage VSL1.

That is, the stacked structure unit voltage Vb provided between the first interconnection 50 and the second interconnection 80 is divided depending on the relationship between the resistance (in the high resistance state or in the low resistance state) of the resistance change layer 130 and the resistance of the rectifying element 70 when the positive polarity voltage and the negative polarity voltage are applied, and thus the resistance change layer voltage Va is determined. Therefore, the first interconnection signal voltage VSL1 and the second interconnection signal voltage VSL2 are set so that the electric field in the resistance change layer 130 during applying the second signal S2 is smaller than the electric field during applying the first signal S1.

In this way, the control unit 300 improves the data retention characteristics by applying the stacked structure unit voltage Vb having a waveform which combines the first interconnection signal SL1 with the second interconnection signal SL2 with a polarity reverse to the first interconnection signal SL1 as shown in FIG. 2B.

Because the polarity of the first signal S1 and the polarity of the second signal S2 are reverse to each other, the polarity of the first interconnection signal SL1 and the polarity of the second interconnection signal SL2 are reverse to each other. In other words, when the polarity of the first interconnection signal SL1 and the polarity of the second interconnection signal SL2 are reverse to each other, the polarity of the first signal S1 and the polarity of the second signal S2 are reverse to each other.

Therefore, in this embodiment, in the set operation, the signal (first interconnection signal SL1) with the first polarity and the signal (second interconnection signal SL2) with the second polarity reverse to the first polarity are applied between the first interconnection 50 and the second interconnection 80, and thereby the signal (first signal S1) with the first polarity and the signal (second signal S2) with the second polarity reverse to the first polarity are applied between the first conductive layer 110 and the second conductive layer 120 (resistance change layer 130). Thereby, the charges trapped in the resistance change layer 130 are de-trapped.

Japanese Patent Application No. 2007-134512 discloses an initializing method by applying multiple voltage pulses with a different polarity alternately to a variable resistance element (bipolar type resistance change element) in which the resistance value changes by applying voltages with different polarity. This method is implemented in order to form a conducting path (filament) in the bipolar type resistance change element and multiple voltages with different polarity are applied alternately because of the bipolar type. That is, in this method, multiple voltages with different polarity are applied alternately to the resistance change element, and this is for performing set operation and reset operation repeatedly in a pseudo manner and not for de-trapping.

In contrast, in this embodiment, the second signal S2 is applied for de-trapping and not for the rest operation. Therefore, the multiple first signals S1 and the multiple second signals S2 are not necessary to be applied alternately and the second signal S2 is applied at least once after the first signal S1 for the set operation is applied.

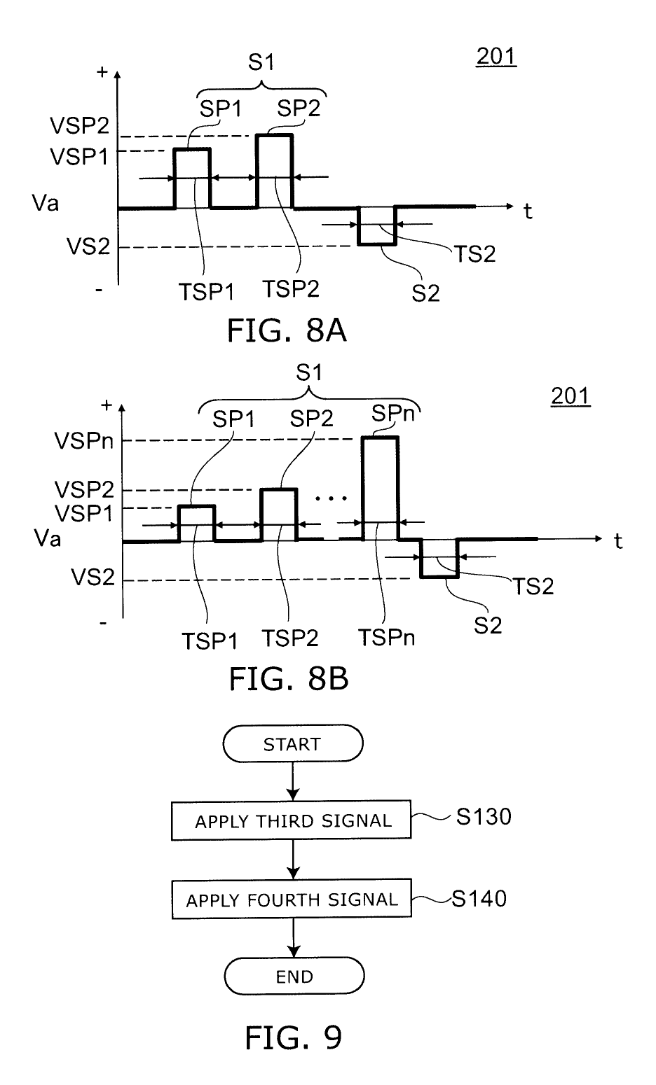

FIGS. 8A and 8B are schematic views illustrating the operation of the nonvolatile memory device according to the first embodiment of the invention.

As shown in FIG. 8A, the first signal S1 may include multiple pulses. In this specific example, the first signal S1 includes two pulses (first set pulse SP1 and second set pulse SP2).

The first set pulse SP1 has the first polarity. The first set pulse SP1 has a first set pulse voltage VSP1. An applied time of the first set pulse SP1 is a first set pulse time TSP1.

The second set pulse SP2 is applied after the application of the first set pulse SP1. The second set pulse SP2 has the first polarity. The second set pulse SP2 has a second set pulse voltage VSP2. An applied time of the second set pulse SP2 is a second set pulse time TSP2.

The absolute value of the second set pulse voltage VSP2 and the second set pulse time TSP2 are arbitrary. For example, the absolute value of the second set pulse voltage VSP2 may be the same as the absolute value of the first set pulse voltage VSP1 and may be smaller than the absolute value of the first set pulse voltage VSP1. The second set pulse time TSP2 may be the same as the first set pulse time TSP1 and may be shorter than the first set pulse time TSP1.

As illustrated in FIG. 8A, at least one of that the absolute value of the set pulse voltage VSP2 is larger than the absolute value of the first set pulse voltage VSP1 and that the second set pulse time TSP2 is longer than the first set pulse time TSP1 may be enforced.

Furthermore, as shown in FIG. 8B, the first signal S1 may include three or more pulses (first set pulse SP1 to n-th set pulse SPn). Here, n is an integer of three or more. The case where n is two corresponds to the operation illustrated in FIG. 8A.

The first set pulse SP1 has the first polarity, as well. The first set pulse SP1 has the first set pulse voltage VSP1. The applied time of the first set pulse SP1 is the first set pulse time TSP1.

The n-th set pulse SPn is applied after the (n-1)-th set pulse SP(n-1) is applied. The n-th set pulse SPn has the first polarity.

The absolute value of the n-th set pulse voltage VSPn being a voltage of the n-th set pulse SPn and the n-th set pulse time TSPn being an applied time of the n-th set pulse SPn are arbitrary. For example, the absolute value of the n-th set pulse voltage VSPn may be substantially the same as the absolute value of the (n-1)-th set pulse voltage VSP(n-1) being a voltage of the (n-1)-th set pulse SP(n-1) and may be smaller than the absolute value of the (n-1)-th set pulse voltage VSP(n-1). The n-th set pulse time TSPn may be the same as the (n-1)-th set pulse time TSP(n-1) being an applied time of the (n-1)-th set pulse SP(n-1) and may be shorter than the (n-1)-th set pulse time TSP(n-1).

As illustrated in FIG. 8B, at least one of that the absolute value of the n-th set pulse voltage VSPn is larger than the absolute value of the (n-1)-th set pulse voltage VSP(n-1) and that the n-th set pulse time TSPn is longer than the (n-1)-th set pulse time TSP(n-1) may be enforced.

That is, the first signal S1 can include multiple set pulses. This allows the resistance change layer 130 to transit to the low resistance state from the high resistance state with a good controllability. The first signal S1 may include multiple set pulses, where at least one of the absolute value of the voltage and the applied time of the multiple set pulses increases sequentially.

Thus, the first signal S1 may include the first set pulse SP1 with the first polarity and the second set pulse SP2 with the first polarity which is applied after the first set pulse SP1 is applied. For example, at least one of that the absolute value of the voltage of the second set pulse SP2 is larger than the absolute value of the voltage of the first set pulse SP1 and that the applied time of the second set pulse SP2 is longer than the applied time of the first set pulse SP1 may be enforced.

Similarly to the description with regard to FIG. 2B, the first interconnection signal SL1 applied between the first interconnection 50 and the second interconnection 80 can includes a first interconnection set pulse with the first polarity and a second interconnection set pulse with the second polarity which is applied after the first interconnection set pulse is applied. For example, at least one of that the absolute value of the voltage of the second interconnection set pulse is larger than the absolute value of the voltage of the first interconnection set pulse and that the applied time of the second interconnection set pulse is longer than the applied time of the first interconnection set pulse may be enforced.

In this case as well, the second signal S2 applied for de-trapping may be one pulse. However, the embodiment is not limited thereto, the second signal S2 may include multiple pulses and the number of pulses included in the second signal S2 is arbitrary.

When the resistance state of the resistance change layer 130 becomes different from the desired state due to applying the second signal S2, repeating of applying the first signal S1 again and thereafter applying the second signal S2 may be performed.

The interval from the application of the first signal S1 to the application of the second signal S2 is preferable to be short from the viewpoint of shortening the operation time of the nonvolatile memory device 201.

### Second Embodiment

FIG. 9 is a flow chart illustrating the operation of a nonvolatile memory device according to a second embodiment of the invention.

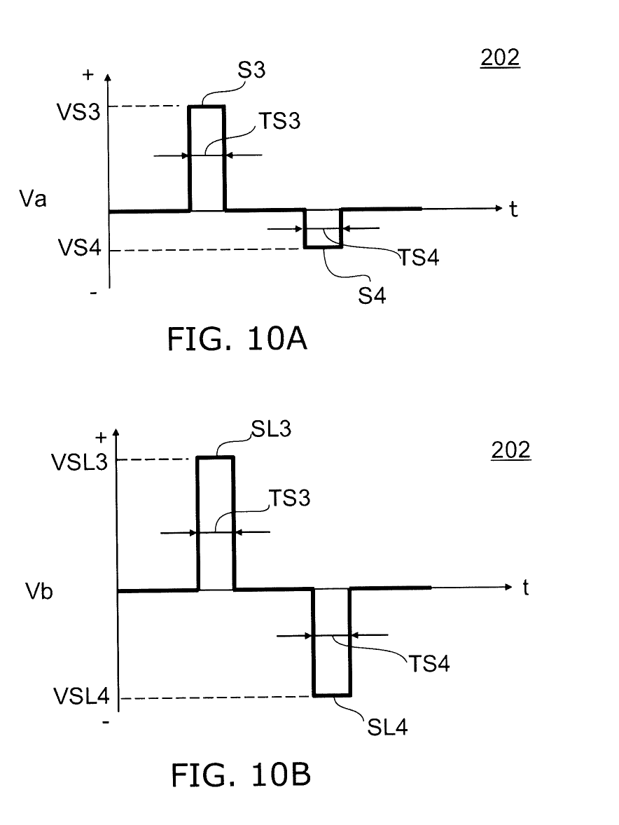

FIGS. 10A and 10B are schematic views illustrating the operation of the nonvolatile memory device according to the second embodiment of the invention.

That is, FIGS. 10A and 10B illustrate the resistance change layer voltage Va and the stacked structure unit voltage Vb in the nonvolatile memory device 202 according to the second embodiment, respectively. In these figures, the horizontal axis indicates time t, the vertical axis in FIG. 10A indicates the resistance change layer voltage Va and the vertical axis in FIG. 10B indicates the stacked structure unit voltage Vb. The configuration of the nonvolatile memory device 202 according to this embodiment may be the same as that of the nonvolatile memory device 201, and thus the description is omitted.

As shown in FIG. 9 and FIG. 10A, the control unit 300 of the nonvolatile memory device 202 according to this embodiment applies a third signal S3 with a first polarity between the first conductive layer 110 and the second conductive layer 120 (step 130), and then applies a fourth signal with a second polarity different from the first polarity between the first conductive layer 110 and the second conductive layer 120 (step S140) to cause the resistance change layer 130 to transit from the low resistance state to the high resistance state (the reset operation).

In this specific example, the first polarity is the positive polarity and the second polarity is the negative polarity, but the first polarity may be the negative polarity and the second polarity may be the positive polarity.

Thus, in the reset operation, the resistance change layer voltage Va includes the third signal S3 and the fourth signal S4 which is applied after the third signal S3 is applied.

For example, the third signal S3 is a signal for the reset operation. The fourth signal S4 with a polarity reverse to the third signal S3 is a signal for de-trapping charges trapped in the resistance change layer 130.

A voltage of the third signal S3 is taken as a third signal voltage VS3, and an applied time of the third signal S3 is taken as a third signal time TS3. A voltage of the fourth signal S4 is taken as a fourth signal voltage VS4, and an applied time of the fourth signal S4 is taken as a fourth signal time TS4. A magnitude of the third signal voltage VS3 corresponds to a magnitude of the electric field in the resistance change layer 130 when the third signal S3 is applied. A magnitude of the fourth signal voltage VS4 corresponds to a magnitude of the electric field in the resistance change layer 130 when the fourth signal S4 is applied.

At least one of that the absolute value of the fourth signal voltage VS4 is smaller than the absolute value of the third signal voltage VS3 and that the fourth signal time TS4 is shorter than the third signal time TS3 may be enforced.

That is, a magnitude of an electric field in the resistance change layer 130 when the fourth signal S4 is applied is smaller than a magnitude of an electric field in the resistance change layer 130 when the third signal S3 is applied. A time (fourth signal time TS4) during the application of the electric field by the fourth signal S4 to the resistance change layer 130 is shorter than a time (third signal time TS3) during the application of the electric field by the third signal S3 to the resistance change layer 130.

Thus, after the third signal S3 for the reset operation is applied to the resistance change layer 130, the fourth signal S4 with the polarity reverse to the third signal S3 having a small absolute value of the voltage and/or a short applied time is applied to the resistance change layer 130. Thereby the charges trapped in the resistance change layer 130 are preliminary de-trapped with substantially no bad effect to the resistance state (high resistance state under the reset state) of the resistance change layer 130. Thus, the change of the internal electric field in the resistance change layer 130 during the later data retention can be suppressed and a nonvolatile memory device with excellent data retention characteristics can be provided.

Here, it is preferable that the absolute value of the effective electric field applied to the resistance change layer 130 by the above fourth signal S4 is larger than 0 MV/cm and not more than approximately 10 MV/cm. Thereby, de-trapping can be performed with substantially no change in the characteristics of the resistance change layer 130.

The fourth signal time TS4 being the applied time of the above fourth signal S4 can be set to be not less than 100 ps and not more than 1 ms.

To perform the operation like this, the control unit 300 applies the stacked structure unit voltage Vb having a waveform illustrated in FIG. 10B to the stacked structure unit 65.

That is, in the reset operation, the control unit 300 applies a third interconnection signal SL3 with the first polarity between the first interconnection 50 and the second inter connection 80. After applying the third interconnection signal SL3, the control unit 300 applies a fourth interconnection signal SL4 with the second polarity different from the first polarity between the first interconnection 50 and the second interconnection 80.

The voltage of the third interconnection signal SL3 is taken as a third interconnection signal voltage VSL3. An applied time of the third interconnection signal SL3 is substantially the same as the third signal time TS3. The voltage of the fourth interconnection signal SL4 is taken as a fourth interconnection signal voltage VSL4. An applied time of the fourth interconnection signal SL4 is substantially the same as the fourth signal time TS4.

In this case as well, the third interconnection signal voltage VSL3 is not necessary to be identical to the third signal voltage VS3. The fourth interconnection signal voltage VSL4 is not necessary to be identical to the fourth signal voltage VS4.

The third interconnection signal voltage VSL3 and the fourth interconnection signal voltage VSL4 are set so that the electric field in the resistance change layer 130 during applying the fourth signal S4 is smaller than during applying the third signal S3.

The polarity of the third interconnection signal SL3 and the polarity of the fourth interconnection signal SL4 are reverse to each other, and thus the polarity of the third signal S3 and the polarity of the fourth signal S4 are reverse to each other.

Therefore, in this embodiment, in the reset operation, the signal (third interconnection signal SL3) with the first polarity and the signal (fourth interconnection signal SL4) with the second polarity reverse to the first polarity are applied between the first interconnection 50 and the second interconnection 80, and thereby the signal (third signal S3) with the first polarity and the signal (fourth signal S4) with the second polarity reverse to the first polarity are applied between the first conductive layer 110 and the second conductive layer 120 (resistance change layer 130). Thereby, the charges trapped in the resistance change layer 130 are de-trapped.

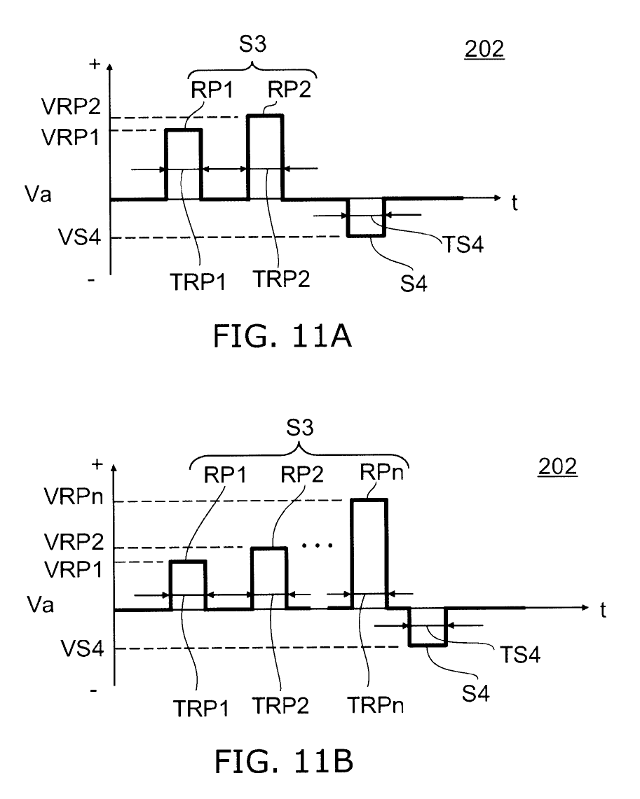

FIGS. 11A and 11B are schematic views illustrating the operation of the nonvolatile memory device according to the second embodiment of the invention.

As shown in FIG. 11A, the third signal S3 may include multiple pulses. In this specific example, the third signal S3 includes two pulses (first reset pulse RP1 and second reset pulse RP2).

The first reset pulse RP1 has the first polarity. The first reset pulse RP1 has a first reset pulse voltage VRP1. An applied time of the first reset pulse RP1 is a first reset pulse time TRP1.

The second reset pulse RP2 is applied after the first reset pulse RP1 is applied. The second reset pulse RP2 has the first polarity. The second reset pulse RP2 has a second reset pulse voltage VRP2. An applied time of the second reset pulse RP2 is a second reset pulse time TRP2.

The absolute value of the second reset pulse voltage VRP2 and the second reset pulse time TRP2 are arbitrary. For example, the absolute value of the second reset pulse voltage VRP2 may be the same as the absolute value of the first reset pulse voltage VRP1 and may be smaller than the absolute value of the first reset pulse voltage VRP1. The second reset pulse time TRP2 may be the same as the first reset pulse time TRP1 and may be shorter than the first reset pulse time TRP1.

As illustrated in FIG. 11A, at least one of that the absolute value of the second reset pulse voltage VRP2 is larger than the absolute value of the first reset pulse voltage VRP1 and that the second reset pulse time TRP2 is longer than the first reset pulse time TRP1 may be enforced.

Furthermore, as shown in FIG. 11B, the third signal S3 may include three or more pulses (first reset pulse RP1 to n-th reset pulse RPn). Here, n is an integer of three or more. The case where n is two corresponds to the operation illustrated in FIG. 11A.

The first reset pulse RP1 has the first polarity as well. The first reset pulse RP1 has the first reset pulse voltage VRP1. The applied time of the first reset pulse RP1 is the first reset pulse time TRP1.

The n-th reset pulse RPn is applied after the (n-1)-th reset pulse RP(n-1) is applied. The n-th reset pulse RPn has the first polarity.

The absolute value of the n-th reset pulse voltage VRPn being a voltage of the n-th reset pulse RPn and the n-th reset pulse time TRPn being an applied time of the n-th reset pulse RPn are arbitrary. For example, the absolute value of the n-th reset pulse voltage VRPn may be substantially the same as the absolute value of the (n-1)-th reset pulse voltage VRP(n-1) being a voltage of the (n-1)-th reset pulse RP(n-1) and may be smaller than the absolute value of the (n-1)-th reset pulse voltage VRP(n-1). The n-th reset pulse time TRPn may be the same as the (n-1)-th reset pulse time TRP(n-1) being an applied time of the (n-1)-th reset pulse RP(n-1) and may be shorter than the (n-1)-th reset pulse time TRP(n-1).

As illustrated in FIG. 11B, at least one of that the absolute value of the n-th reset pulse voltage VRPn is larger than the absolute value of the (n-1)-th reset pulse voltage VRP(n-1) and that the n-th reset pulse time TRPn is longer than the (n-1)-th reset pulse time TRP(n-1) may be enforced.

That is, the third signal S3 can include multiple reset pulses. This allows the resistance change layer 130 to transit to the high resistance state from the low resistance state with a good controllability. The third signal S3 may include multiple reset pulses, where at least one of the absolute value of the voltage and the applied time of the multiple reset pulses increases sequentially.

Thus, the third signal S3 may include the first reset pulse RP1 with the first polarity and the second reset pulse RP2 with the first polarity which is applied after the first reset pulse RP1 is applied. For example, at least one of that the absolute value of the voltage of the second reset pulse RP2 is larger than the absolute value of the voltage of the first reset pulse RP1 and that the applied time of the second reset pulse RP2 is longer than the applied time of the first reset pulse RP1 may be enforced

At this time as well, the third interconnection signal SL3 applied between the first interconnection 50 and the second interconnection 80 can include a first interconnection reset pulse with the first polarity and a second interconnection reset pulse with the first polarity which is applied after the first interconnection reset pulse is applied. For example, at least one of that the absolute value of the voltage of the second interconnection reset pulse is larger than the absolute value of a voltage of the first interconnection reset pulse and that the applied time of the second interconnection reset pulse is longer than the applied time of the first interconnection reset pulse may be enforced.

In this case as well, the fourth signal S4 applied for de-trapping may be one pulse. However, this embodiment is not limited thereto, the fourth signal S4 may include multiple pulses and the number of pulses included in the fourth signal S4 is arbitrary.

When the resistance state of the resistance change layer 130 becomes different from the desired state due to applying the fourth signal S4, repeating of applying the third signal S3 again and thereafter applying the fourth signal S4 may be performed.

The interval from the application of the third signal S3 to the application of the fourth signal S4 is preferable to be short from the viewpoint of shortening the operation time of the nonvolatile memory device 202.

In the nonvolatile memory device 202 according to this embodiment, the operation described with regard to the nonvolatile memory device 201 can be further implemented.

That is, the control unit 300 applies the first signal S1 with the first polarity between the first conductive layer 110 and the second conductive layer 120 prior to applying the second signal S2 with the second polarity different from the first polarity between the first conductive layer 110 and the second conductive layer 120 to cause the resistance change layer 130 to transit from the high resistance state to the low resistance state. Furthermore, the control unit 300 applies the third signal S3 with one of the first polarity and the second polarity between the first conductive layer 110 and the second conductive layer 120 prior to applying the fourth signal S4 with the other one of the first polarity and the second polarity to cause the resistance change layer 130 to transit from the low resistance state to the high resistance state. Namely, the control unit 300 applies the third signal S3 between the first conductive layer 110 and the second conductive layer 120 prior to applying a fourth signal S4 with a polarity different from a polarity of the third signal S3 between the first conductive layer 110 and the second conductive layer 120 to cause the resistance change layer 130 to transit from the low resistance state to the high resistance state. This allows the nonvolatile memory device with excellent data retention characteristics in both cases of the set operation and the reset operation to be provided.

The first embodiment and the second embodiment can be applied to both a unipolar type nonvolatile memory device in which the set operation and the reset operation are performed with the same polarity and a bipolar nonvolatile memory device in which the set operation and the reset operation are performed with reverse polarity to each other. Also in the bipolar type nonvolatile memory device, the absolute value and the applied time of the voltage of the second signal S2 and the fourth signal S4 for de-trapping are set in a range without false operation (false set operation and false reset operation) of the resistance change layer 130, and thereby the effect described with regard to the above embodiments can be obtained and the data retention characteristics can be improved.

### Third Embodiment

A third embodiment of the invention relates to a method for manufacturing a nonvolatile memory device. The nonvolatile memory device to which this manufacturing method is applied may have the same configuration as the nonvolatile memory device 201 according to the first embodiment. That is, the nonvolatile memory device to which this manufacturing method is applied includes the memory layer 60 including the first conductive layer 110, the second conductive layer 120, and the resistance change layer 130 provided between the first conductive layer 110 and the second conductive layer 120 and configured to transit between the high resistance state and the low resistance state having the resistance lower than the resistance in the high resistance state by at least one of the applied electric field and applied current.

In this embodiment, the control unit 300 applies a set pulse between the first conductive layer 110 and the second conductive layer 120 to cause the resistance change layer 130 to transit from the high resistance state to the low resistance state, and applies a reset pulse having a polarity identical to the polarity of the set pulse between the first conductive layer 110 and the second conductive layer 120 to cause the resistance change layer 130 to transit from the low resistance state to the high resistance state.

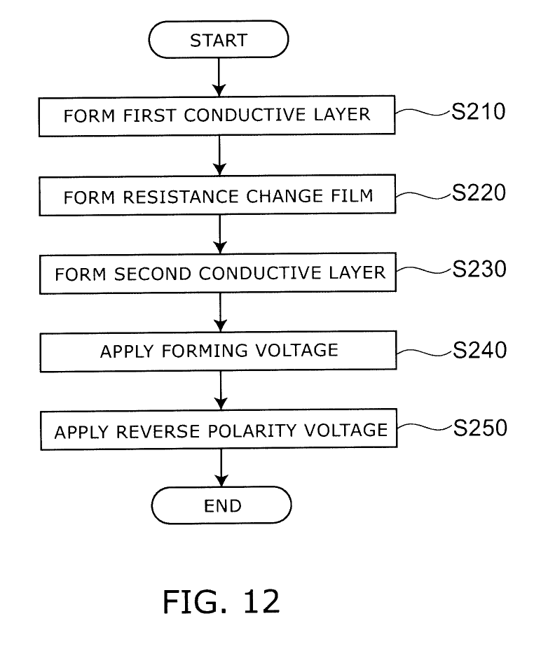

FIG. 12 is a flow chart illustrating a method for manufacturing a nonvolatile memory device according to a third embodiment of the invention.

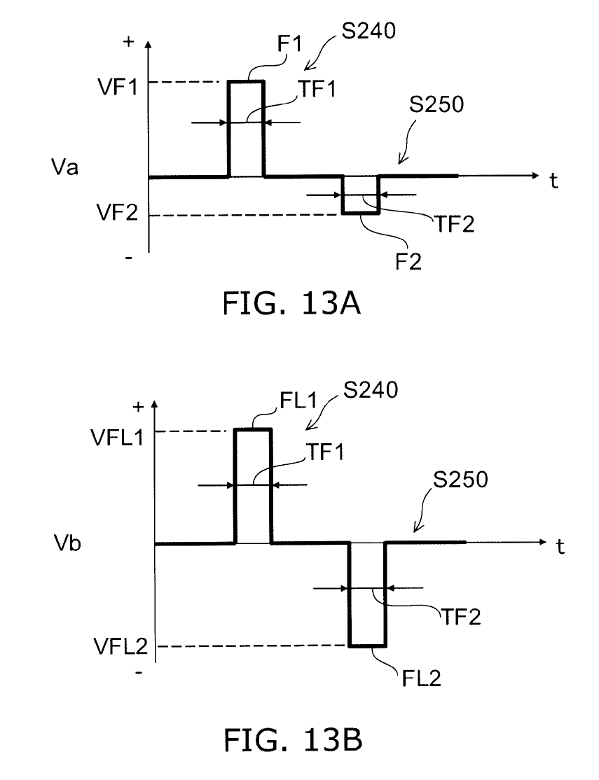

FIGS. 13A and 13B are schematic views illustrating the method for manufacturing a nonvolatile memory device according to the third embodiment of the invention.

FIGS. 13A and 13B illustrate the resistance change layer voltage Va and the stacked structure unit voltage Vb applied in the method for manufacturing the nonvolatile memory device according to the third embodiment, respectively. In these figures, the horizontal axis indicates time t, the vertical axis in FIG. 13A indicates the resistance change layer voltage Va and the vertical axis in FIG. 13B indicates the stacked structure unit voltage Vb.

As shown in FIG. 12, in this manufacturing method, the first conductive layer 110 is formed on a substrate, for example (step S210). A resistance change film serving as the resistance change layer 130 is formed above the first conductive layer 110 (step S220). Then, the second conductive layer 120 is formed above the resistance change film (step S230).

Thereafter, a forming voltage with the first polarity between the first conductivity layer 110 and the second conductivity layer 120 is applied to form a current path in the above resistance change film and to form the resistance change layer 130 (step S240). Subsequently, a reverse polarity voltage with the second polarity different from the first polarity is applied between the first conductivity layer 110 and the second conductivity layer 120 (step S250).

That is, as shown in FIG. 13A, in step S240, a forming voltage F1 with the first polarity (positive polarity in this specific example) is applied between the first conductivity layer 110 and the second conductivity layer 120. In step S250, a reverse polarity voltage F2 with the second polarity (negative polarity in this specific example) is applied between the first conductivity layer 110 and the second conductivity layer 120.

In this specific example, the first polarity is a positive polarity and the second polarity is a negative polarity, however the first polarity may be the negative polarity and the second polarity may be the positive polarity.

Thus, in the manufacturing method according to this embodiment, in the forming treatment to form the current path in the resistance change film to form the resistance change layer 130, the forming voltage F1 is applied and the reverse polarity voltage F2 is applied after the forming voltage F1 is applied.

For example, the forming voltage F1 is a voltage to form the current path (for example, filament 131) in the resistance change film. The reverse polarity voltage F2 is a signal to de-trap charges trapped in the resistance change layer 130 during the application of the forming voltage F1.

A voltage of the forming voltage F1 is taken as a forming voltage value VF1. An applied time of the forming voltage F1 is taken as a forming voltage applied time TF1. A voltage of the reverse polarity voltage F2 is taken as a reverse polarity voltage value VF2. An applied time of the reverse polarity voltage F2 is taken as a reverse polarity voltage applied time TF2. A magnitude of the forming voltage value VF1 corresponds to a magnitude of an electric field in the resistance change film (resistance change layer 130) when the forming voltage F1 is applied. A magnitude of the reverse polarity voltage value VF2 corresponds to a magnitude of an electric field in the resistance change film (resistance change layer 130) when the reverse polarity voltage F2 is applied.

At least one of that the absolute value of the reverse polarity voltage value VF2 is smaller than the absolute value of the forming voltage value VF1 and that the reverse polarity voltage applied time TF2 is shorter than the forming voltage applied time TF1 may be enforced.

That is, a magnitude of an electric field in the resistance change film (resistance change layer 130) when the reverse polarity voltage F2 is applied is smaller than a magnitude of an electric field in the resistance change film (resistance change layer 130) when the forming voltage F1 is applied. The time (reverse polarity voltage applied time TF2) during the application of the electric field by the reverse polarity voltage F2 to the resistance change film (resistance change layer 130) is shorter than the time (forming voltage applied time TF1) during the application of the electric field by the forming voltage F1 to the resistance change film (resistance change layer 130).

Thus, after the forming voltage F1 for forming is applied to the resistance change film (resistance change layer 130), the reverse polarity voltage F2 with the polarity reverse to the forming voltage F1 and having a small absolute value of the voltage and/or a short applied time is applied to the resistance change film (resistance change layer 130). Thereby the charges trapped in the resistance change film (resistance change layer 130) during applying the forming voltage F1 are preliminary de-trapped with substantially no bad effect to the forming state of the filament 131 in the resistance change film (resistance change layer 130). Thus, the change of the internal electric field in the resistance change layer 130 during the data retention in use of a nonvolatile memory device after the forming treatment can be suppressed and a nonvolatile memory device with excellent data retention characteristics can be provided.

Here, it is preferable that the absolute value of the effective electric field applied to the resistance change film (resistance change layer 130) by the above reverse polarity voltage F2 is larger than 0 MV/cm and not more than approximately 10 MV/cm. Thereby, de-trapping can be performed with substantially no change in the characteristics of the resistance change layer 130.

For example, when HfO₂ having a relative dielectric constant of 20 is used as the resistance change film (resistance change layer 130) and a thickness of the resistance change film (resistance change layer 130) is 10 nm (nanometer), the reduced thickness of the resistance change film (resistance change layer 130) as a silicon oxide film is approximately about 2 nm. Therefore, the absolute value of the reverse polarity voltage value VF2 of the reverse polarity voltage F2 is set so that a voltage larger than 0 V and not more than approximately 2 V is applied to the resistance change film (resistance change layer 130).

The reverse polarity voltage applied time TF2 being the applied time of the above reverse polarity voltage F2 can be set to be not less than 100 ps and not more than 1 ms.

To perform the operation like this, the control unit 300 applies the stacked structure unit voltage Vb having a waveform illustrated in FIG. 13B between the first interconnection 50 and the second inter connection 80.

That is, the control unit 300 applies a forming interconnection voltage FL1 with the first polarity between the first interconnection 50 and the second inter connection 80 in the forming. The control unit 300 applies a reverse polarity interconnection voltage FL2 with the second polarity different from the first polarity between the first interconnection 50 and the second interconnection 80 after applying the forming interconnection voltage FL1.

The voltage of the forming interconnection voltage FL1 is taken as a forming interconnection voltage value VFL1. An applied time of the forming interconnection voltage FL1 is substantially the same as the forming voltage applied time TF1. The voltage of the reverse polarity interconnection voltage FL2 is taken as a reverse polarity interconnection voltage value VFL2. An applied time of the reverse polarity interconnection voltage FL2 is substantially the same as the reverse polarity voltage applied time TF2.

In this case as well, the forming interconnection voltage value VFL1 is not necessary to be identical to the forming voltage value VF1. The reverse polarity interconnection voltage value VFL2 is not necessary to be identical to the reverse polarity voltage value VF2.

The forming interconnection voltage value VFL1 and the reverse polarity interconnection voltage value VFL2 are set so that the electric field in the resistance change film (resistance change layer 130) during applying the reverse polarity voltage F2 is smaller than during applying the forming voltage F1.

The polarity of the forming interconnection voltage FL1 and the polarity of the reverse polarity interconnection voltage FL2 are reverse to each other, and thus the polarity of the forming voltage F1 and the polarity of the reverse polarity voltage F2 are reverse to each other.

Therefore, in this embodiment, in the forming, the voltage (forming interconnection voltage FL1) with the first polarity and the voltage (reverse polarity interconnection voltage FL2) with the second polarity reverse to the first polarity are applied between the first interconnection 50 and the second interconnection 80, and thereby the voltage (forming voltage F1) with the first polarity and the voltage (reverse polarity voltage F2) with the second polarity reverse to the first polarity are applied between the first conductive layer 110 and the second conductive layer 120 (resistance change film serving as the resistance change layer 130). This de-traps the charges trapped in the resistance change film (resistance change layer 130).

In the method for manufacturing the nonvolatile memory device according to this embodiment, at least one of the step S240 and the step S250 may be performed under the condition of at least one of high temperature environment and light irradiation environment of ultraviolet light or the like. The de-trap of the charges from the resistance change film (resistance change layer 130) by applying the reverse polarity voltage F2 can be promoted by performing the step S250 under the high temperature environment and the light irradiation environment. The trap of the charges in the resistance change film (resistance change layer 130) can be suppressed by performing the step S240 under the high temperature environment and the light irradiation environment. This allows the data retention characteristics to be better.

For example, it is preferable to perform the step S240 and the step S250 in a temperature range not less than 80° C. and not more than approximately 250° C. The de-trap effect of charges is promoted with higher temperature in performing of the step S240 and the step S250. However, when a temperature higher than 250° C. is applied, in some cases, the reliability of a nonvolatile device may be decreased by a change of crystalline state of the resistance change film (resistance change layer 130) and the like.

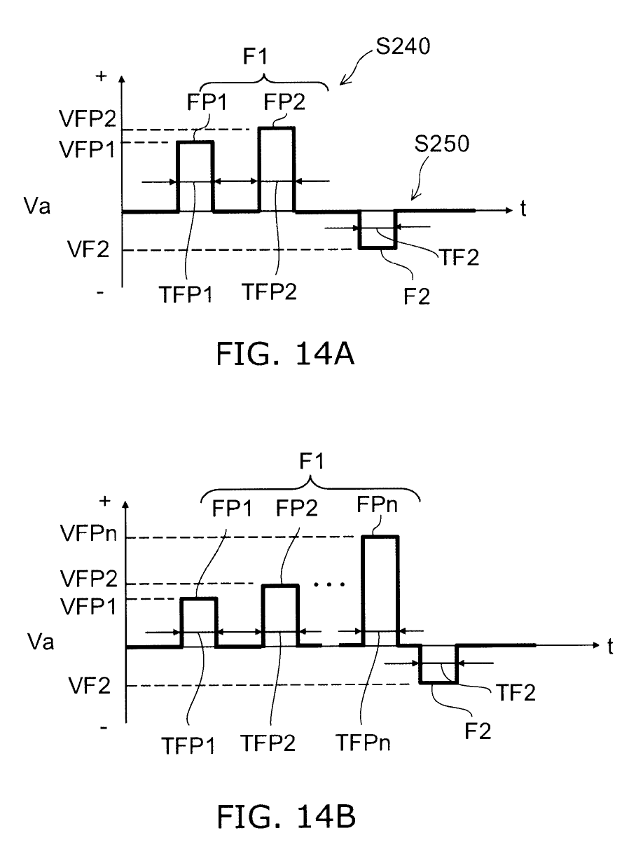

FIGS. 14A and 14B are schematic views illustrating the method for manufacturing a nonvolatile memory device according to the third embodiment.

As shown in FIG. 14A, the forming voltage F1 may include a plurality of pulses. In this specific example, the forming voltage F1 includes two pulses (first forming pulse FP1 and second forming pulse FP2).

The first forming pulse FP1 has the first polarity. The first forming pulse FP1 has a first forming pulse voltage value VFP1. An applied time of the first forming pulse F1 is a first forming pulse applied time TFP1.

The second forming pulse FP2 is applied after the forming pulse FP1 is applied. The second forming pulse FP2 has the first polarity. The second forming pulse FP2 has a second forming pulse voltage value VFP2. An applied time of the second forming pulse FP2 is a second forming pulse applied time TFP2.

The absolute value of the second forming pulse voltage value VFP2 and the second forming pulse applied time TFP2 are arbitrary. For example, the absolute value of the second forming pulse voltage value VFP2 may be the same as the absolute value of the first forming pulse voltage value VFP1 and may be smaller than the absolute value of the first forming pulse voltage value VFP1. The second forming pulse applied time TFP2 may be the same as the first forming pulse applied time TFP1 and may be shorter than the first forming pulse applied time TFP1.

As shown in FIG. 14A, at least one of that the absolute value of the second forming pulse voltage value VFP2 is larger than the absolute value of the first forming pulse voltage value VFP1 and that the second forming pulse applied time TFP2 is longer than the first forming pulse applied time TFP1 may be enforced.

As shown in FIG. 14B, the forming voltage F1 may include three or more pulses (first forming pulse FP1 to n-th forming pulse FPn). Here, n is an integer of three or more. The case where n is two corresponds to the operation illustrated in FIG. 14A.

The first forming pulse FP1 has the first polarity as well. The first forming pulse FP1 has the first forming pulse voltage value VFP1. The applied time of the first forming pulse F1 is the first forming pulse applied time TFP1.

The n-th forming pulse FPn is applied after the (n-1)-th forming pulse FP(n-1) is applied. The n-th forming pulse FPn has the first polarity.

The absolute value of the n-th forming pulse voltage value VFPn being a voltage of the n-th forming pulse FPn and the n-th forming pulse applied time TFPn being an applied time of the n-th forming pulse FPn are arbitrary. For example, the absolute value of the n-th forming pulse voltage value VFPn may be the same as the absolute value of the (n-1)-th forming pulse voltage value VFP(n-1) being the voltage of the (n-1)-th forming pulse FP(n-1) and may be smaller than the absolute value of the (n-1)-th forming pulse voltage value VFP(n-1). The n-th forming pulse applied time TFPn may be the same as the (n-1)-th forming pulse applied time TFP(n-1) being an applied time of the (n-1)-th forming pulse FP(n-1) and may be shorter than the (n-1)-th forming pulse applied time TFP(n-1).

As shown in FIG. 14B, at least one of that the absolute value of the n-th forming pulse voltage value VFPn is larger than the absolute value of the (n-1)-th forming pulse voltage value VFP(n-1) and that the n-th forming pulse applied time TFPn is longer than the (n-1)-th forming pulse applied time TFP(n-1) may be enforced.

That is, the forming voltage F1 can include multiple forming pulses. This allows the filament 131 to be formed with a good controllability and stability. The forming voltage F1 may include multiple forming pulses, where at least one of the absolute value of the voltage and the applied time of the multiple forming pulses increases sequentially.

Thus, the forming voltage F1 may include the first forming pulse FP1 with the first polarity and the second forming pulse FP2 with the first polarity which is applied after the first forming pulse FP1 is applied. For example, at least one of that the absolute value of the voltage of the second forming pulse FP2 is larger than the absolute value of the voltage of the first forming pulse FP1 and that the applied time of the second forming pulse FP2 is longer than the applied time of the first forming pulse FP1 may be enforced.

At this time as well, the forming interconnection voltage FL1 applied between the first interconnection 50 and the second interconnection 80 can include a first interconnection forming pulse with the first polarity and a second interconnection forming pulse with the first polarity which is applied after the first interconnection forming pulse is applied. For example, at least one of that the absolute value of the voltage of the second interconnection forming pulse is larger than the absolute value of the voltage of the first interconnection forming pulse and that the applied time of the second interconnection forming pulse is longer than the applied time of the first interconnection forming pulse may be enforced.

In this case as well, the reverse polarity voltage F2 applied for de-trapping may be one pulse. However, this embodiment is not limited thereto, the reverse polarity voltage F2 may include multiple pulses and the number of pulses included in the reverse polarity voltage F2 is arbitrary.

When the resistance state of the resistance change layer 130 becomes different from the desired state due to applying the reverse polarity voltage F2, repeating of applying the forming voltage F1 again and thereafter applying the reverse polarity voltage F2 may be performed.

The interval from the application of the forming voltage F1 to application of the reverse polarity voltage F2 is preferable to be short from the viewpoint of the efficiency of a manufacturing process of a nonvolatile memory device.

As described above, according to this embodiment of the invention, a nonvolatile memory device having excellent data retention characteristics and a method for manufacturing the same are provided.

In this specification, “perpendicular” and “parallel” are not always exactly perpendicular and parallel and include, for example, variation in the manufacturing process.

In the above, embodiments of the invention have been described with reference to specific examples, however the invention is not limited to these specific examples. For example, specific configurations of various components used in nonvolatile memory device such as the first conductive layer, the second conductive layer, the resistance change layer, the resistance change film, the rectifying element and interconnection or the like that are suitably selected from the publicly known ones by those skilled in the art are encompassed within the scope of the invention as long as the configurations can implement the invention similarly and achieve the same effects.

Components in two or more of the specific examples can be combined with each other as long as technically feasible, and such combinations are also encompassed within the scope of the invention as long as they fall within the spirit of the invention.

The nonvolatile memory device and the method for manufacturing the same described above as the embodiments of the invention can be suitably modified and practiced by those skilled in the art, and such modifications are also encompassed within the scope of the invention as long as they fall within the spirit of the invention.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

1. A nonvolatile memory device comprising:
a memory layer including:
a first conductive layer;
a second conductive layer; and
a resistance change layer provided between the first conductive layer and the second conductive layer, the resistance change layer being configured to transit between a high resistance state and a low resistance state having a resistance lower than a resistance in the high resistance state by at least one of an applied electric field and an applied current; and
a control unit electrically connected to the first conductive layer and the second conductive layer, the control unit being configured to apply a first signal with a first polarity between the first conductive layer and the second conductive layer prior to applying a second signal with a second polarity different from the first polarity between the first conductive layer and the second conductive layer to cause the resistance change layer to transit from the high resistance state to the low resistance state.

2. The device according to claim 1, wherein an absolute value of a voltage of the second signal is smaller than an absolute value of a voltage of the first signal.

3. The device according to claim 1, wherein an applied time of the second signal is shorter than an applied time of the first signal.

4. The device according to claim 1, wherein
the first signal includes:
a first set pulse with the first polarity; and
a second set pulse with the first polarity applied after the first set pulse is applied.

5. The device according to claim 4, wherein the second set pulse has at least one of an absolute value of a voltage larger than an absolute value of a voltage of the first set pulse and an applied time longer than an applied time of the first set pulse.

6. The device according to claim 1, further comprising:
a rectifying element connected to at least one of the first conductive layer and the second conductive layer.

7. The device according to claim 1, wherein
the control unit applies a third signal between the first conductive layer and the second conductive layer prior to applying a fourth signal with a polarity different from a polarity of the third signal between the first conductive layer and the second conductive layer to cause the resistance change layer to transit from the low resistance state to the high resistance state.

8. The device according to claim 7, wherein an absolute value of a voltage of the fourth signal is smaller than an absolute value of a voltage of the third signal.

9. The device according to claim 7, wherein an applied time of the fourth signal is shorter than an applied time of the third signal.

10. A nonvolatile memory device comprising:
a memory layer including:
a first conductive layer;
a second conductive layer; and
a resistance change layer provided between the first conductive layer and the second conductive layer, the resistance change layer being configured to transit between a high resistance state and a low resistance state having a resistance lower than a resistance in the high resistance state by at least one of an applied electric field and an applied current; and
a control unit electrically connected to the first conductive layer and the second conductive layer, the control unit being configured to apply a third signal with a first polarity between the first conductive layer and the second conductive layer prior to applying a fourth signal with a second polarity different from the first polarity between the first conductive layer and the second conductive layer to cause the resistance change layer to transit from the low resistance state to the high resistance state.

11. The device according to claim 10, wherein an absolute value of a voltage of the fourth signal is smaller than an absolute value of a voltage of the third signal.

12. The device according to claim 10, wherein an applied time of the fourth signal is shorter than an applied time of the third signal.

13. The device according to claim 10, wherein
the third signal includes:
a first reset pulse with the first polarity; and
a second reset pulse with the first polarity applied after the first reset pulse is applied.

14. The device according to claim 13, wherein the second reset pulse has at least one of an absolute value of a voltage larger than an absolute value of a voltage of the first reset pulse and an applied time longer than an applied time of the first reset pulse.

15. The device according to claim 10, further comprising:
a rectifying element connected to at least one of the first conductive layer and the second conductive layer.

16. A method for manufacturing a nonvolatile memory device including:
a memory layer including:
a first conductive layer;
a second conductive layer; and
a resistance change layer provided between the first conductive layer and the second conductive layer and configure to transit between a high resistance state and a low resistance state having a resistance lower than a resistance in the high resistance state by at least one of an applied electric field and an applied current,
a control unit electrically connected to the first conductive layer and the second conductive layer, the control unit being configured to apply a set pulse with a first polarity between the first conductive layer and the second conductive layer to cause the resistance change layer to transit from the high resistance state to the low resistance state, and apply a reset pulse with the first polarity between the first conductive layer and the second conductive layer to cause the resistance change layer to transit from the low resistance state to the high resistance state.
the method comprising:
forming the first conductive layer;
forming a resistance change film serving as the resistance change layer above the first conductive layer;
forming the second conductive layer above the resistance change film; and
applying a forming voltage between the first conductive layer and the second conductive layer to form a current path in the resistance change film prior to applying a reverse polarity voltage between the first conductive layer and the second conductive layer, the reverse polarity voltage having a polarity different from a polarity of the forming voltage.

17. The method according to claim 16, wherein an absolute value of a voltage value of the reverse polarity voltage is smaller than an absolute value of a voltage value of the forming voltage.

18. The method according to claim 16, wherein an applied time of the reverse polarity voltage is shorter than an applied time of the forming voltage.

19. The method according to claim 16, wherein
the forming voltage includes:
a first forming pulse with a polarity identical to the polarity of the forming voltage; and
a second forming pulse with a polarity identical to the polarity of the forming voltage, the second forming pulse being applied after the first forming pulse is applied.

20. The method according to claim 19, wherein the second forming pulse has at least one of an absolute value of a voltage larger than an absolute value of a voltage of the first forming pulse and an applied time longer than an applied time of the first forming pulse.
